(19) United States
(12) Patent Application Publication
(10) Pub. No.: US 2018/0374975 A1
(43) Pub. Date: Dec. 27, 2018

(54) COMPOSITIONS FOR UV SEQUESTRATION AND METHODS OF USE

(71) Applicants: Arturo A. AYON, San Antonio, TX (US); Ulises TRONCO-JURADO, San Antonio, TX (US); Rosendo Lopez DELGADO, San Antonio, TX (US); Aldo Zazueta RAYNAUD, San Antonio, TX (US); J. Elias Pelayo CEJA, San Antonio, TX (US); Hiram Higuera VALENZUELA, San Antonio, TX (US); Dainet Berman MENDOZA, San Antonio, TX (US); Antonio Ramos CARRAZCO, San Antonio, TX (US)

(72) Inventors: Arturo A. AYON, San Antonio, TX (US); Ulises TRONCO-JURADO, San Antonio, TX (US); Rosendo Lopez DELGADO, San Antonio, TX (US); Aldo Zazueta RAYNAUD, San Antonio, TX (US); J. Elias Pelayo CEJA, San Antonio, TX (US); Hiram Higuera VALENZUELA, San Antonio, TX (US); Dainet Berman MENDOZA, San Antonio, TX (US); Antonio Ramos CARRAZCO, San Antonio, TX (US)

(73) Assignee: THE BOARD OF REGENTS OF THE UNIVERSITY OF TEXAS SYSTEM, Austin, TX (US)

(21) Appl. No.: 15/563,050

(22) PCT Filed: Apr. 1, 2016
(86) PCT No.: PCT/US2016/025660

§ 371 Date: Sep. 29, 2017

Related U.S. Application Data
(60) Provisional application No. 62/141,596, filed on Apr. 1, 2015.

(51) Int. Cl. H01L 31/055; H01L 31/0216; C09K 11/02; C09K 11/88

(52) U.S. Cl. CPC H01L 31/055; H01L 31/02167; B82Y 20/00; C09K 11/883; C09K 11/025

(57) ABSTRACT

Embodiments are directed to compositions comprising photoluminescent elements (e.g., quantum dots) that absorb UV radiation and emit longer wavelength non-ultraviolet radiation (luminescent down shifting), effectively sequestering the UV radiation. In certain aspects the photoluminescent elements are dispersed on or in a material. In a further aspect the material is transparent to light. In one respect the photoluminescent elements are dispersed in a transparent film.

This application claims priority to U.S. Provisional Patent Application Ser. No. 62/141,596 filed Apr. 1, 2015, which is herein incorporated by reference in its entirety.

### BACKGROUND

Ultraviolet (UV) light is electromagnetic radiation with a wavelength from 400 nm to 10 nm. UV radiation is present in sunlight, and is produced by electric arcs and specialized lights such as mercury-vapor lamps, tanning lamps, and black lights. Suntan and sunburn are familiar effects of over-exposure to UV radiation, along with higher risk of skin cancer in animals. UV light also has been shown to be detrimental to plants, which include reduction of photosynthetic capacity (Correia et al. Field Crops Research 62:97-115, 1999; Reddy et al. Biometry, Modeling & Statistics 105(5):1367-76, 2013; Kataria et al., Journal of Photochemistry and Photobiology B: Biology 137:55-66, 2014). Living things on dry land would be severely damaged by ultraviolet radiation from the sun if most of the UV radiation were not filtered out by the Earth's atmosphere.

There is a need for compositions and methods for protecting objects, animals (including humans), and plants from UV radiation, as well as converting UV radiation to a more beneficial wavelength.

### SUMMARY

Embodiments are directed to compositions comprising photoluminescent elements (e.g., quantum dots) that absorb UV radiation and emit longer wavelength non-ultraviolet radiation (luminescent down shifting), effectively sequestering the UV radiation. In certain aspects the photoluminescent elements are dispersed on or in a material. In a further aspect the material is transparent to light. In one respect the photoluminescent elements are dispersed in a transparent film. In another respect the photoluminescent elements are dispersed in or on a transparent material, such as glass, Plexiglas, or the like. In still further aspects the photoluminescent elements are applied to the surface of an object, e.g., spray coating or via an atomizer. The compositions described herein can be used as windows in homes, cars, buildings, and greenhouses. In other aspects the films described herein can be used on windows or panels in homes, cars, buildings, or greenhouses. In a particular aspect a film or window in a greenhouse will emit non-UV wavelength light that can be used by a plant or organism being raised or grown in the greenhouse while reducing the amount of UV irradiation exposure.

Certain embodiments are directed to a film for coating windows, solar cells, and other surfaces in need of UV radiation sequestration or protection from UV. In certain aspects the photoluminescent elements emit longer wavelength non-UV radiation that can be absorbed by a device or material that is in contact with or in the proximity of the photoluminescent elements, or otherwise dispersed as non-UV emissions. In a further embodiment the photoluminescent elements are on the surface of a solar cell or positioned between the solar cell and a light source where the UV radiation is sequestered by the photoluminescent elements, which in turn emit at a wavelength of radiation that is then utilized by the solar cell.

In certain aspects the photoluminescent elements are quantum dots, carbon nanospheres, or carbon nanotubes. In certain respects the photoluminescent elements exploit the ability of quantum dots or similar compositions to absorb high-energy photons and luminesce at longer wavelengths (e.g., down shift UV light). Photoluminescent elements can include CdTe, CdSe, CdS, PbS, and ZnO quantum dots. An aspect of particular interest is the strong dependence of luminescence wavelength on the dimensions of the photoluminescent elements enabling the tuning of the photons emitted. In terms of preparation, quantum dots have the added advantage that they can be synthesized by relatively affordable chemical methods.

Certain embodiments are directed to quantum dot (QD) based luminescent down shifting nanostructures. In certain aspects the quantum dots are CdTe quantum dots. In certain respects the synthesized nanostructures can be described as nanocrystalline quantum dots comprising II/VI compounds. In certain aspects the quantum dots are capped.

In certain embodiments wet-chemical preparation methods can be employed to synthesize nanocrystals (NCs) in colloidal solutions for ultimately producing QDs with high photoluminescence quantum yields (PL QYs), narrow size distribution, and tunable sizes and shapes that have relatively minor variations in the size of the synthetized quantum dots.

In a further embodiment photoluminescent elements as described herein can be mechanically mixed with a polymer, molten, or liquid material that subsequently polymerizes or solidifies forming a film or structure having photoluminescent elements dispersed throughout the structure or material. In other aspects the photoluminescent elements can be sprayed or coated in a solvent or solution that dries or evaporates leaving behind a photoluminescent element coating. In particular respects a solution or polymer comprising photoluminescent elements can be spun-cast on a surface. In certain respect the photoluminescent elements described herein are present at a density of at least, at most, or about 10, 100, 1000, 1×10⁴, 1×10⁵, 1×10⁶, 1×10⁷ photoluminescent elements or particles per cubic mm or photoluminescent elements or particles per milligram, including all values and ranges there between. In certain aspects the film, coating, or solidified material is at least, at most, or about 5, 50, 100, 200, 300, 400, 500, 1000 nm to about 0.5, 1, 2, 3, 4, 5, 6, 7, 8, 9, 10 mm in thickness, including all values and ranges there between. In certain aspects the thickness of film, coating, or material is minimized to reduce parasitic optical loss.

Other embodiments of the invention are discussed throughout this application. Any embodiment discussed with respect to one aspect of the invention applies to other aspects of the invention as well and vice versa. Each embodiment described herein is understood to be embodiments of the invention that are applicable to all aspects of the invention. It is contemplated that any embodiment discussed herein can be implemented with respect to any method or composition of the invention, and vice versa. Furthermore, compositions and kits of the invention can be used to achieve methods of the invention.

The use of the word “a” or “an” when used in conjunction with the term “comprising” in the claims and/or the specification may mean “one,” but it is also consistent with the meaning of “one or more,” “at least one,” and “one or more than one.”

Throughout this application, the term “about” is used to indicate that a value includes the standard deviation of error for the device or method being employed to determine the value.

The use of the term “or” in the claims is used to mean “and/or” unless explicitly indicated to refer to alternatives only or the alternatives are mutually exclusive, although the disclosure supports a definition that refers to only alternatives and “and/or.”

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

Other objects, features and advantages of the present invention will become apparent from the following detailed description. It should be understood, however, that the detailed description and the specific examples, while indicating specific embodiments of the invention, are given by way of illustration only, since various changes and modifications within the spirit and scope of the invention will become apparent to those skilled in the art from this detailed description.

### DESCRIPTION OF THE DRAWINGS

The following drawings form part of the present specification and are included to further demonstrate certain aspects of the present invention. The invention may be better understood by reference to one or more of these drawings in combination with the detailed description of the specification embodiments presented herein.

FIGS. 1A-1B. (A) Absorption and (B) photoluminescence spectra of CdTe QDs refluxed at different times, namely, 30 min, 1 h, 3 h, 6 h, 8 h, and 12 h.

FIG. 2A-2B. (A) DLS size measurements of CdTe QDs for different refluxing times and (B) TEM image of synthesized CdTe QDs.

FIG. 3. Photoluminescence spectra of CdTe QDs/PMMA downshifting nanostructures deposited by spin coating.

FIG. 4A-4B. Reflectivity of planar c-Si solar cells (A) using different PMMA to QD solution ratios for a fixed spin cast film thickness of 65 nm and employing an Al₂O₃ passivation layer 56 nm thick on the back side, (B) with a PMMA to QD solution ratio of 2:1 for different spin cast film thicknesses and without the Al₂O₃ passivation layer on the back side.

FIG. 5A-5B. Measured J-V characteristic curves (A) for the planar and (B) texturized solar cells of different c-Si thickness with and without CdTe QDs down shifting nanostructures.

FIGS. 6A-6B. Measured EQE for (A) planar and (B) texturized of different thickness c-Si solar cells in comparison without and with the deposition of CdTe QDs down shifting nanostructures.

FIG. 7. Absorption and photoluminescence spectra of CdTe QDs incorporated to the PMMA matrix on the incident surface of the solar cells.

FIG. 8. ZnO quantum dot spectra, excitation wavelength 340 nm.

FIG. 9. ZnO quantum dot spectra, excitation wavelength 345 nm. ZnO QDs have a decreased luminescence in solvents during the process and when dispersed in PMMA have a low luminescent intensity.

FIG. 10. ZnO quantum dot effect on EQE.

FIG. 11. Carbon quantum dot TEM images.

FIG. 12. Carbon quantum dot spectra. The down-shifted emissions of Carbon QDs of various sizes are observed to be centered at ˜405 nm. Quantum Dot size is determined by the applied current during synthesis.

### DESCRIPTION

Embodiments are directed to compositions comprising photoluminescent elements or particles (e.g., quantum dots) that absorb UV radiation and emit longer wavelength non-ultraviolet radiation (luminescent down shifting), effectively sequestering the UV radiation.

Quantum dots (QDs) comprise colloidal semiconductor cores that are small, often spherical, crystalline particles composed of group II-VI, III-V, IV-VI, or semiconductor materials. Quantum dot properties originate from their physical size, which ranges from about 1 to about 10 nanometers (nm) in radius. As a consequence, quantum dots no longer exhibit the optical or electronic properties of their bulk parent semiconductor. Instead, they exhibit novel properties due to what are commonly referred to as quantum confinement effects. These effects originate from the spatial confinement of intrinsic carriers (electrons and holes) to the physical dimensions of the material rather than to bulk length scales. One confinement effect is a size dependent blue shift of the absorption and luminescence emission with decreasing particle size.

The absorption and emission wavelength are determined by the nanocrystal size. Nanocrystals preparations comprise a distribution of sizes. This size distribution dictates the range of wavelength that can be absorbed.

Quantum dots can be enveloped by a layer of surfactant molecules having one or more functional groups that bind to the metal atoms on the quantum dots surface (examples of the functional groups include, but are not limited to, phosphine, phosphine oxide, thiol, amine carboxylic acid, etc.) and one or more moieties on the opposite end from the metal-binding groups to increase the solubility of the quantum dot in a given solvent or matrix material. For example, hydrophobic aliphatic, alkane, alicyclic, and aromatic groups on the distal ends of the surfactant molecules increase the solubility of the quantum dots in hydrophobic solvents, while polar or ionizable groups increase the solubility of the quantum dots in hydrophilic and aqueous solvents.

Microparticles containing quantum dots have been developed by dispersing quantum dots in a liquid phase polymeric matrix materials (examples include various plastics, silicones, and epoxies), curing or drying the composite into a solid form, and then milling the composite into micron scale particles.

Examples of materials suitable for use as quantum dot cores include, but are not limited to, ZnO, ZnS, ZnSe, ZnTe, CdO, CdS, CdSe, CdTe, MgS, MgSe, GaAs, GaN, GaP, GaSe, GaSb, HgO, HgS, HgSe, HgTe, InAs, InN, InP, AlAs, AlN, AlP, AlB, TlN, TlP, TlAs, TlSb, PbO, PbS, PbSe, PbTe, Ge, Si, an alloy including any of the foregoing, and/or a mixture including any of the foregoing.

A semiconductor nanocrystal (including a semiconductor nanocrystal core of a core/shell semiconductor nanocrsytal) can comprise one or more semiconductor materials at least one of which comprises at least one metal and at least one chalcogen. Examples of semiconductor materials include, but are not limited to, Group II-VI compounds (e.g., binary, ternary, and quaternary compositions), Group III-VI compounds (e.g., binary, ternary, and quaternary compositions), Group IV-VI compounds (e.g., binary, ternary, and quaternary compositions), Group II-IV-VI compounds (e.g., binary, ternary, and quaternary compositions), and alloys including any of the foregoing, and/or a mixture including any of the foregoing. Semiconductor nanocrystals can also comprise one or more semiconductor materials that comprise ternary and quaternary alloys that include one or more of the foregoing compounds. Examples of Group II elements include Zn, Cd, and Hg. Examples of Group VI elements include oxygen, sulfur, selenium and tellurium. Examples of Group III elements include boron, aluminum, gallium, indium, and thallium. Examples of Group V elements include nitrogen, phosphorus, arsenic, antimony, and bismuth. Examples of Group IV elements include silicon, germanium, tin, and lead.

Quantum dots are members of a population of quantum dots. The distribution of diameters can also be referred to as a “size.” Preferably, a population of particles includes a population of particles wherein at least about 60% of the particles in the population fall within a specified particle size range. A population of particles preferably deviate less than 15% rms (root-mean-square) in diameter and more preferably less than 10% rms and most preferably less than 5% rms.

Quantum dots of the present invention can have an average particle size in a range from about 1 to about 1000 nanometers (nm), and preferably in a range from about 1 to about 100 nm. In certain embodiments, quantum dots have an average particle size in a range from about 1 to about 20 nm (e.g., such as about 2, 3, 4, 5, 6, 7, 8, 9, 10, 11, 12, 13, 14, 15, 16, 17, 18, 19, or 20 nm).

In certain aspects a QD includes a core material and a capping or shell material, however, uncapped NP's can be used as well. The “core” is a nanoparticle with dimensions of about 1 to 250 nm. The core can include two or more elements. In certain embodiments, the core can be an II-VI semiconductor and can be about 2 nm to 10 nm in diameter. For example, the core can be CdS, CdSe, CdTe, ZnSe, ZnS, ZnS:Ag, ZnO:Ag, PbS, or PbSe. In certain aspects the core is CdTe.

The “cap” or “shell” may be a semiconductor or insulator that differs from or is the same as the semiconductor or insulator of the core and binds to the core, thereby forming a surface layer on the core. A shell can differ from the core and/or other shells by means of its chemical composition, and/or the presence of one or more dopants, and/or different amounts of a given dopant. The shell typically passivates the core by having a higher band gap than the core, and having an energy offset in the top of the valence band and bottom of the conduction band such that electrons and/or holes may be confined to the core by the shell. Each shell encloses, partially (e.g., about 50% or more, about 60% or more, about 70% or more, about 80% or more, about 90% or more, about 95% or more, about 99% or more) or totally, the adjacent shell closer to the core. In one embodiment, the shell can be a IIB-VIA semiconductor of high band gap. For example, the shell can be ZnS or CdS on a core of CdTe. In certain aspects, the shell may also be an organic film, such as silicones, thiophenes, trioctylphosphine, trioctylphosphine oxide, or a combination thereof. The thickness of the shell can be about 0.1 to 20 nm, about 0.1 to 5 nm, or about 0.1 to 2 nm covering the core. In certain aspects a QD is capped using thiols as mercapto succinic acid (MSA), thioglycolic acid (TGA), cysteine, and gluthatione (GSH), among others.

The absorption wavelength can be tuned by varying the composition and the size of the QD and/or adding one or more shells around the core in the form of concentric shells.

Compositions Containing Photoluminescent Elements

UV barrier films are well known in the art. Such films may comprise organic or inorganic UV blockers. The organic blockers are also called UV absorbers more generally UV protecting compositions because they mainly absorb, and thereby protect the film substrate, from the effects of UV rays.

Polymeric films are used in a number of applications. Polypropylene films, particularly biaxially oriented polypropylene (BOPP) films, are often used in food packaging due to their transparency, high stiffness, thermal stability and low cost. However, problems may occur when the film is exposed to UV radiation. The photodegradation of BOPP is an oxygen diffusion controlled process. The irradiation is strong at the surface of the polymer but falls off in the interior. In general, UV irradiation causes chain scission, void formation, and other structural changes in BOPP which critically reduce its mechanical properties. Of the solar wavelengths, the UV-B component is particularly effective in photo-damaging materials.

In certain aspects photoluminescent elements are incorporated into or onto a film to provide for protection of the film or for use as a protective film. The flexible polymeric film can be a web based material such as paper, a polymer film or flexible laminate material comprising one or more polymeric film substrates. The flexible polymer film substrate may be a polymer material such as polypropylene or polyethylene or polymethylene. In certain aspects the polymer film can be polymethyl methacrylate (PMMA).

In certain respects the polymer film can be a multilayer structure formed by any suitable method (such as co-extrusion and/or lamination) with one or more UV protecting layers provided on the surface of an outermost layer of the structure. The numbers of UV protecting layers provided on the polymer film substrate depends on the end application in which the polymer film is used.

The photoluminescent elements described herein can be incorporated into or dispersed throughout a rigid material such as glass, Plexiglas, or a rigid polymeric article.

In certain applications a material incorporating photoluminescent material as described herein can be coupled to a device that utilizes light at a wavelength longer than UV, wherein the photoluminescent elements absorb UV light and emit a longer wave length (blue shift). In certain aspects the photoluminescent material can be coupled to a photovoltaic device.

### EXAMPLES

The following examples as well as the figures are included to demonstrate preferred embodiments of the invention. It should be appreciated by those of skill in the art that the techniques disclosed in the examples or figures represent techniques discovered by the inventors to function well in the practice of the invention, and thus can be considered to constitute preferred modes for its practice. However, those of skill in the art should, in light of the present disclosure, appreciate that many changes can be made in the specific embodiments which are disclosed and still obtain a like or similar result without departing from the spirit and scope of the invention.

### Example 1

### Photoluminescent Film for Improving the Efficiency of Solar Cells

Certain embodiments are directed to CdTe quantum dot based luminescent down shifting nanostructures on c-Silicon Solar Cells. The synthetized nanostructures can be described as nanocrystalline CdTe QD consisting of II/VI compounds, capped by Thioglycolic acid (TGA). Wet-chemical preparation methods can be successfully employed for synthesizing nanocrystals (NCs) in colloidal solutions for ultimately producing QDs with high photoluminescence quantum yields (PL QYs), narrow size distribution, and tunable sizes and shapes that have relatively minor variations in the size of the synthetized CdTe quantum dots that enable the shifting toward wavelengths of interest for single crystal silicon solar cells.

The power conversion efficiency of photovoltaic devices is anticipated to benefit from the utilization of the photoluminescent (PL) nanostructures mechanically mixed with PMMA and subsequently spin-cast on previously fabricated photovoltaic structures. The fabrication and characterization effort of photovoltaic structures comprising CdTe quantum-dot luminescent down-shifting layers on the radiation incident surface, included the concentration per weight of the synthesized QDs as well as the thickness and refractive index of the coatings employed. The observations indicate that thinner films are generally preferred to minimize parasitic optical losses. The observed increases in open circuit voltage as well as short circuit current could promote the proliferation of the described structures for harvesting solar energy.

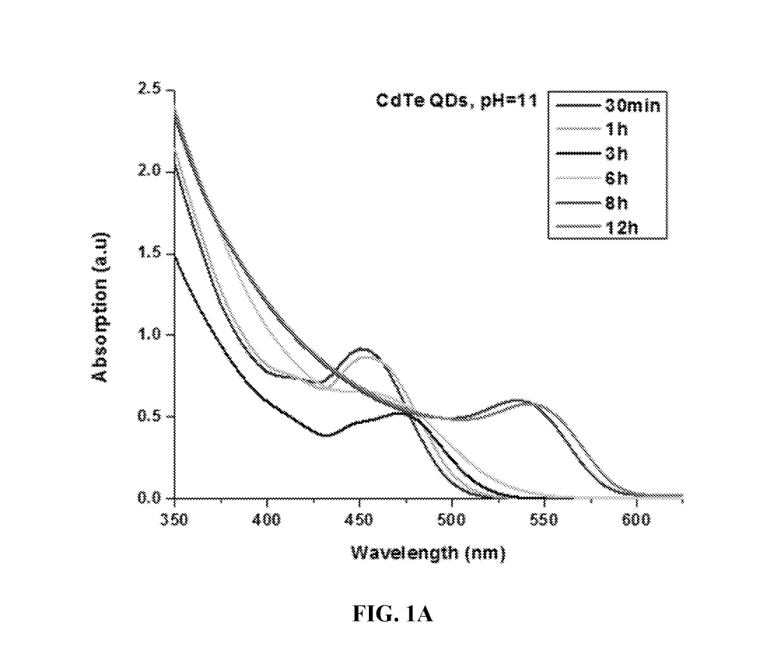

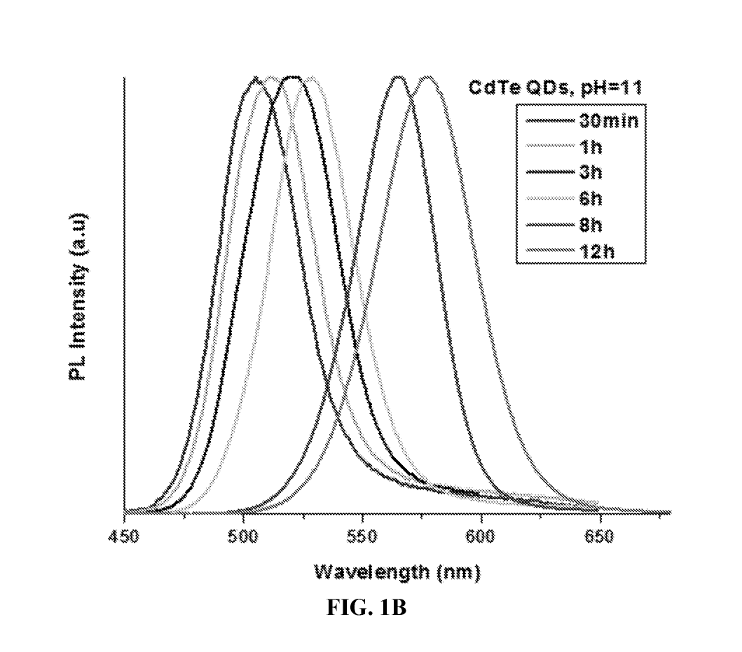

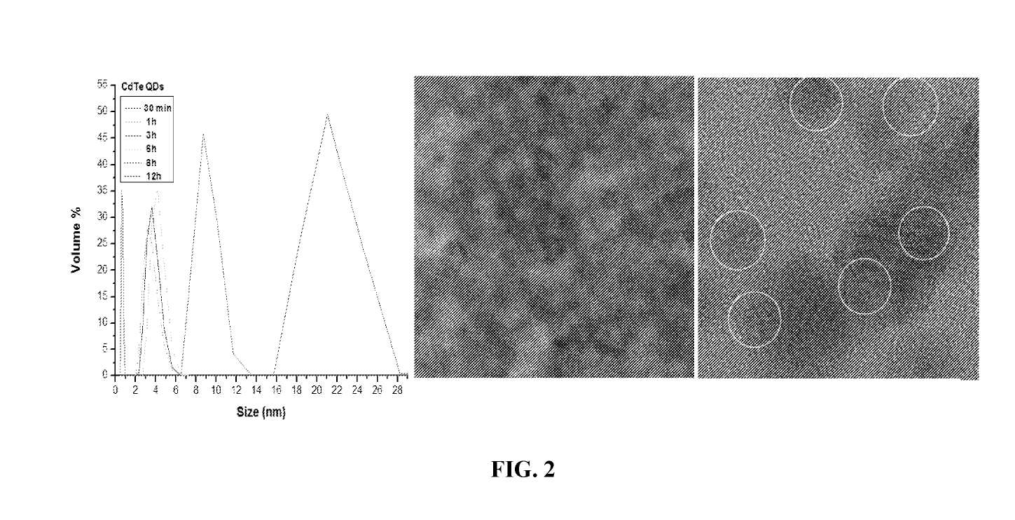

FIG. 1 depicts the absorption and photoluminescence spectra of the synthetized CdTe QDs refluxed at different times. Ostensibly the synthesized QDs absorb wavelengths below 550 nm where a c-Si solar cell is relatively inefficient and reemit at longer wavelengths approaching 600 nm where solar cells are rather efficient. DLS analysis indicates that the refluxing time determines the size of the synthesized QDs. Thus, as the refluxing time was varied from 30 minutes to 12 hours, the corresponding QD sizes were measured to extend from 16 to 28 nm (FIG. 2).

Luminescent Down Shifting Nanostructures of CdTe QDs/PMMA Characterization.

PMMA is considered an appropiate host polymer for embedding the synthesized CdTe QDs which, upon spin casting, resulted in homogeneous films with a noticeable variation in thickness and refractive index as a function of the spin coating speed employed (see Table 1). The films were subsequently incorporated on the radiation incident surface of the c-Silicon solar cells.

TABLE 1
Thickness and refractive index of the CdTe QDs/PMMA
down shifting films spin cast at different rotational speeds
measured employing a Rudolph AutoELIII ellipsometer.
CdTe QDs/PMMA

| Casting speed (rpm) | Thickness (nm) | Refractive index |
|---|---|---|
| 1000 | 100 | 1.519 |
| 2000 | 75 | 1.522 |
| 3000 | 65 | 1.526 |
| 4000 | 59 | 1.536 |

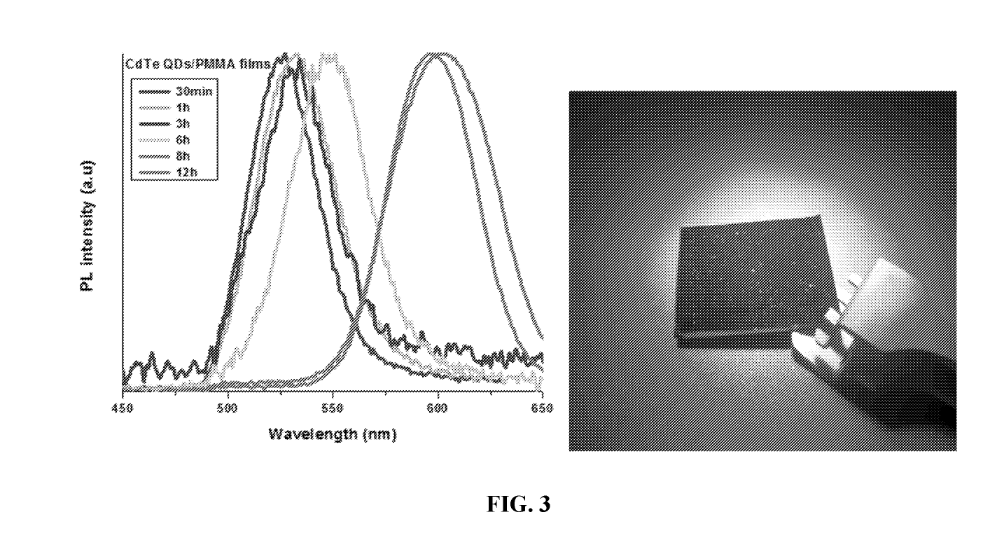

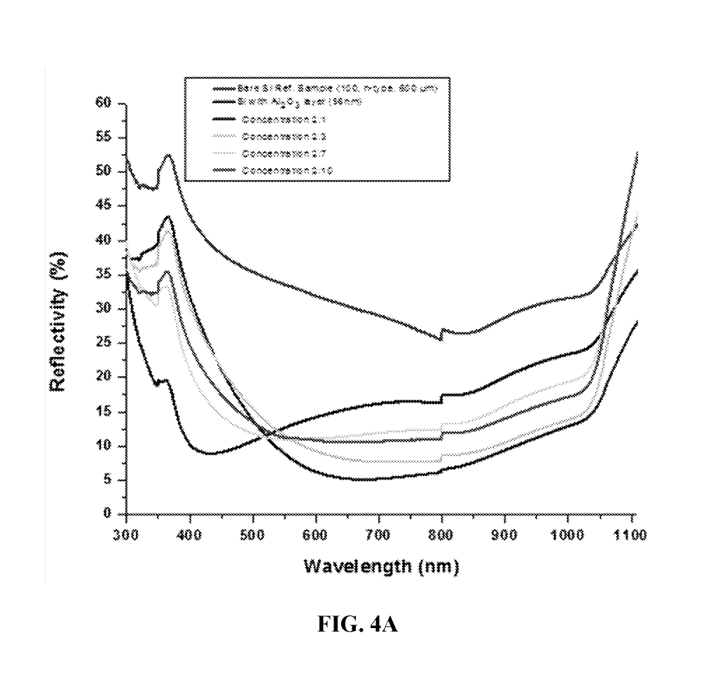

The photoluminescence measurements of the spin cast PMMA films with the dispersed CdTe QDs, exhibited a small but important variation in the PL spectrum. Namely, the spectra were broader and shifted approximately 22 nm to longer wavelengths (see FIG. 3) respect to the values collected for the QDs in solution and reported in FIG. 1B. This effect is thought to be due to the variation in the electrical properties of the surrounding medium (Suarez et al., Nanotechnology, 2011, 22:435202).

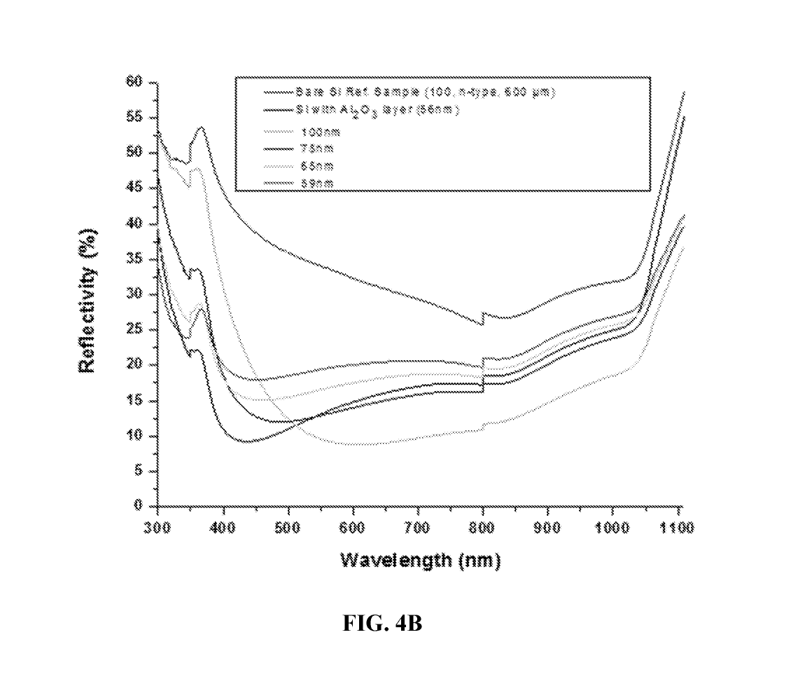

Light trapping optimization of the CdTe QDs/PMMA down shifting nanostructures over the incident surface of the c-Si solar cells. In order to evaluate the performance of c-Si solar cells with the incorporation of the CdTe QDs/PMMA down shifting films over the incident surface of the fabricated devices, preliminary tests were conducted to determine the optimum PMMA to CdTe QD solution ratio, film thickness and to corroborate the benefits of an Al₂O₃ passivation layer 56 nm thick on the back side. FIG. 4A presents the data collected for PMMA+QD spin cast films with a thickness of 65 nm, for different ratios of PMMA to QD solution varying from 2:1 to 2:10, while FIG. 4B presents the data collected for PMMA+QD film thickness variations from 60 to 100 nm while maintaining a PMMA to QD solution ratio of 2:1. The collected graphs were subsequently evaluated by calculating the ultimate efficiency η while assuming no additional losses other than the measured reflected photons. This was accomplished by employing the standard equation:

$$η = \frac{{\int }_{0}^{{λ}_{g}} I ( λ ) A ( λ ) \frac{λ}{λ g} d λ}{{\int }_{0}^{∞} I ( λ ) d λ} \qquad ( 1 )$$

where, I(λ) is Solar intensity per wavelength interval corresponding to an air mass of 1.5 directly normal and a circumsolar spectrum, A(λ) is the absorption, λ is the wavelength and λ_{g} is the wavelength corresponding to the band gap of the c-Si. Based on the aforementioned guiding calculations, a spin cast film thickness of 100 nm and a PMMA to QD solution ratio of 2:1 were selected for all subsequently fabricated solar cells along with a 56 nm Al₂O₃ passivation layer on the back side (Dingemans and Kessels, Journal of Vacuum Science & Technology A, 2012, 30:040802).

PV Performance Measurements.

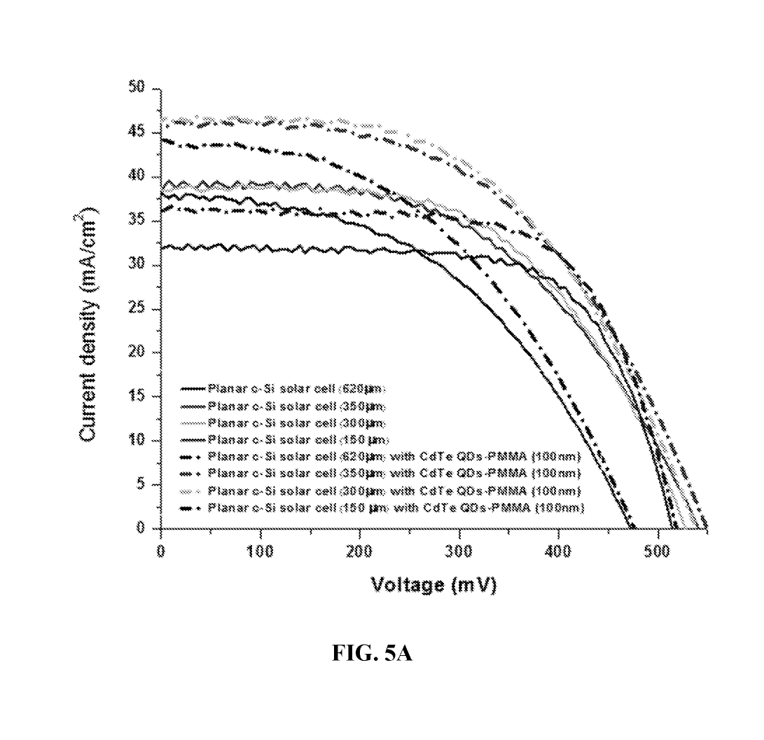

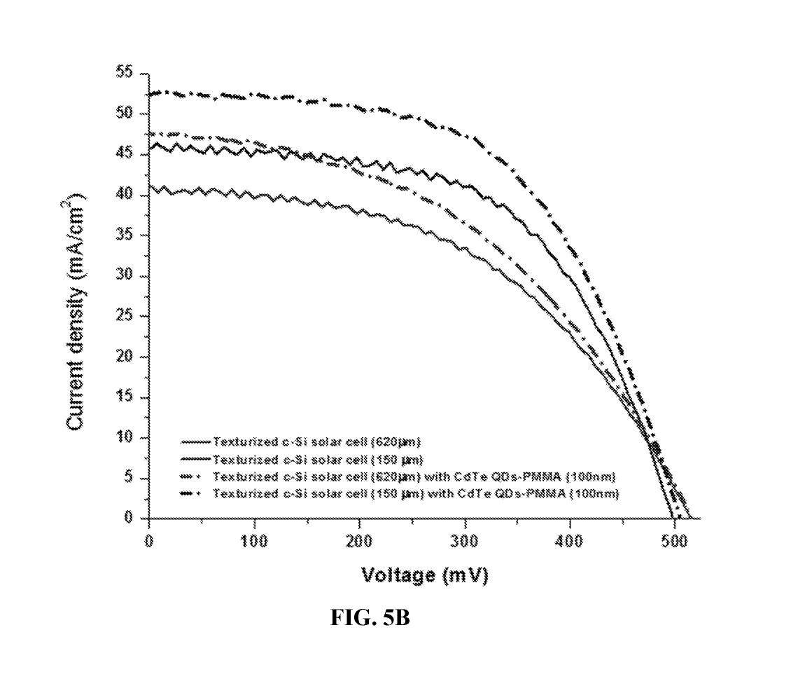

The current density and voltage (J-V) characteristics of the c-Si solar cells to study the effect of the CdTe QDs/PMMA down shifting nanostructures in the performance of the solar cells were measured employing different thickness (620, 350, 300 and 150 μm) of the c-Si solar cells, using planar and texturized samples. FIG. 5A shows the J-V characteristics of the planar solar cells without and with the down shifting nanostructures of CdTe QDs/PMMA under simulated AM 1.5G at 1000 W/m², where the QDs refluxed for 8 h were applied to the PMMA matrix because their close emission to 600 nm. Table 4 summarizes the photovoltaic parameters of open circuit voltage (V_{oc}), short circuit current density (J_{sc}), fill factor (FF) and PCE. Applying the optimum thickness of the down shifting nanostructures (100 nm) calculated from the reflectivity measurements, indicates a direct improvement on the V_{oc} and J_{sc} in each sample which indicate the effect of the CdTe QDs down shifting layer absorbing shorter wavelengths increasing the PCE of each sample approximately 1-1.5% respectively with the bare sample. However, the fill factor tends to decrease with the application of the CdTe QDs, which could be due to the fluorescence quenching of the QDs or the intensity of light that the QDs emitted decreased, such effect is too small does not significantly affect the performance of the planar cells. With thinner c-Si substrate solar cells, an increase on the FF is measured having an improvement in the PCE. Moreover, Table 5 summarizes the texturized samples, where the CdTe QDs down shifting nanostructures were deposited on silicon nanochannel arrays of average pillar height of 400 nm following the same parameters as the planar samples, where the V_{oc} and J_{sc} (FIG. 5B) also enhances as the FF decreases and improvement the PCE of the texturized cells at the same way that occurred on the planar solar cells.

TABLE 2
Average performance of planar solar cells with different
substrate thicknesses (620, 300 and 150 μm).

| | V_{oc} | J_{sc} | | |
|---|---|---|---|---|
| Planar Solar Cell | (mV) | (mA/cm²) | FF(%) | PCE(%) |
| c-Si: 620 μm | 527.6 | 38.6 | 56.7 | 11.6 |
| c-Si: 620 μm with CdTe QDs | 529.0 | 46.4 | 52.0 | 12.6 |
| c-Si: 300 μm | 564.5 | 38.7 | 56.8 | 12.4 |
| c-Si: 300 μm with CdTe QDs | 567.9 | 44.3 | 54.6 | 13.7 |
| c-Si: 150 μm | 536.0 | 37.4 | 63.9 | 12.8 |
| c-Si: 150 μm with CdTe QDs | 540.4 | 43.0 | 61.8 | 14.4 |

TABLE 3
Average performance of randomly texturized solar cells with
different substrate thicknesses (620, 300 and 150 μm).

| | V_{oc} | J_{sc} | | |
|---|---|---|---|---|
| Randomly Texturized Solar Cell | (mV) | (mA/cm²) | FF(%) | PCE(%) |
| c-Si: 620 μm | 534.5 | 41.2 | 55.0 | 12.1 |
| c-Si: 620 μm with CdTe QDs | 534.5 | 47.3 | 52.2 | 13.2 |
| c-Si: 300 μm | 534.2 | 44.7 | 54.7 | 13.0 |
| c-Si: 300 μm with CdTe QDs | 536.7 | 49.2 | 56.6 | 13.9 |
| c-Si: 150 μm | 514.4 | 43.3 | 60.8 | 13.5 |
| c-Si: 150 μm with CdTe QDs | 517.2 | 47.6 | 60.9 | 15.0 |

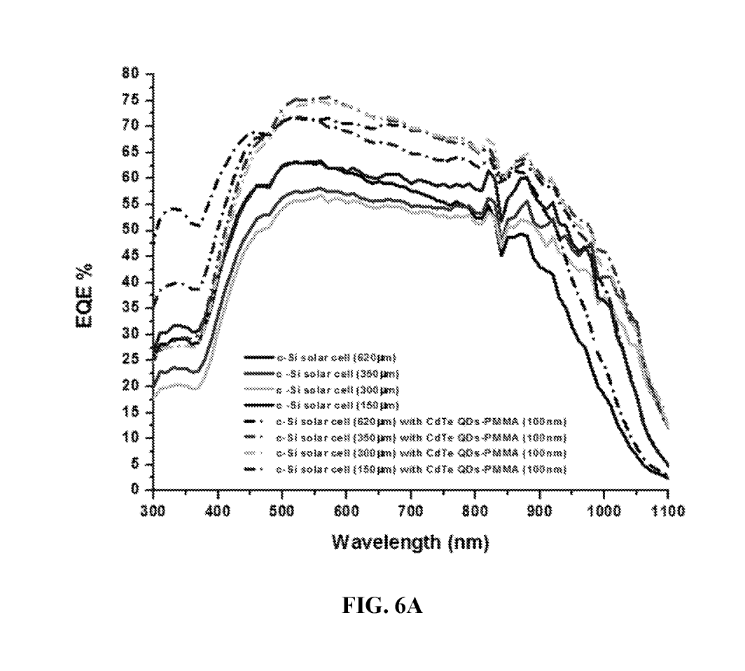

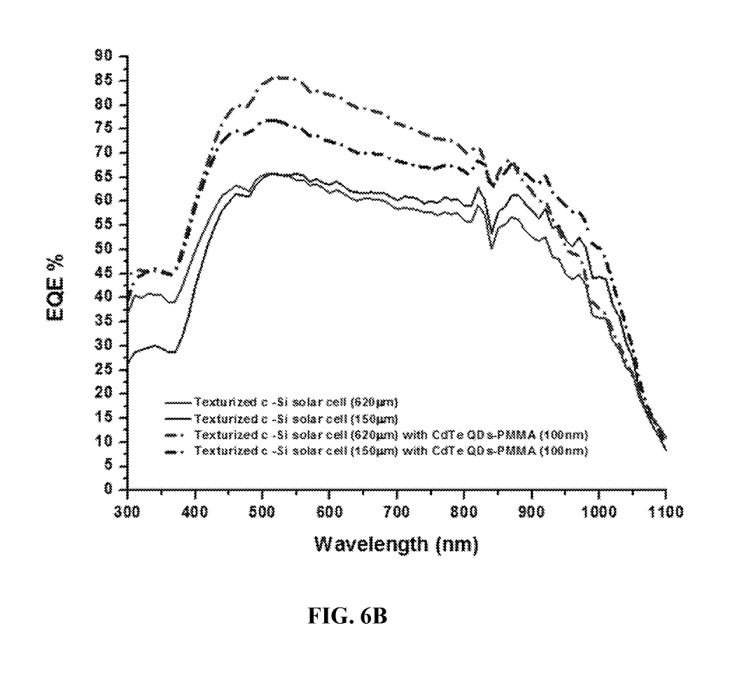

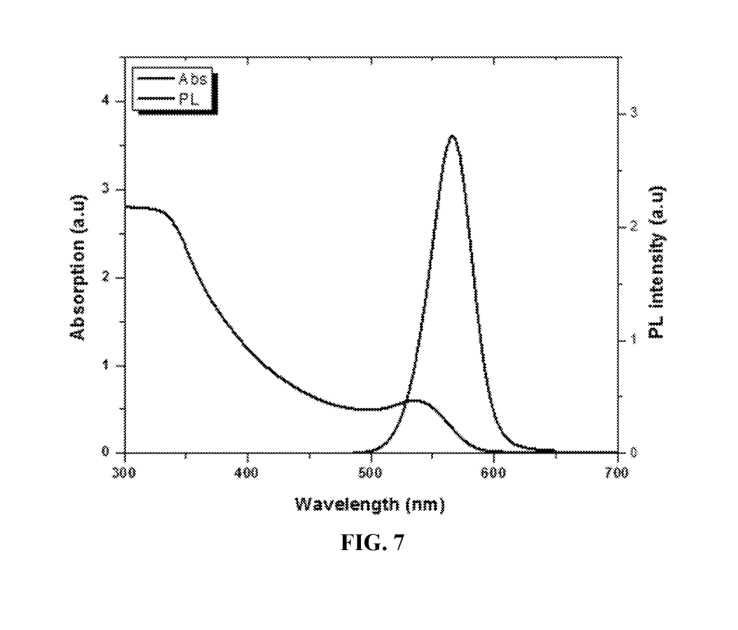

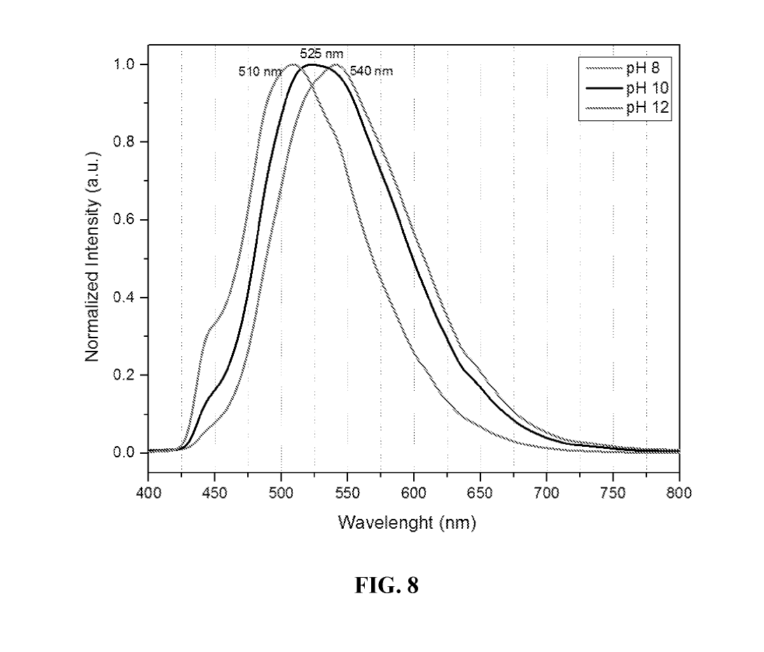

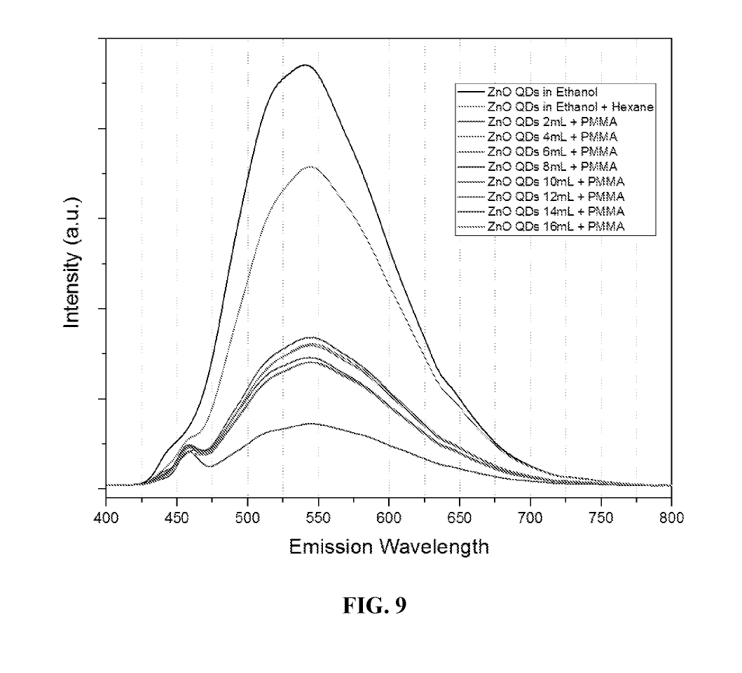

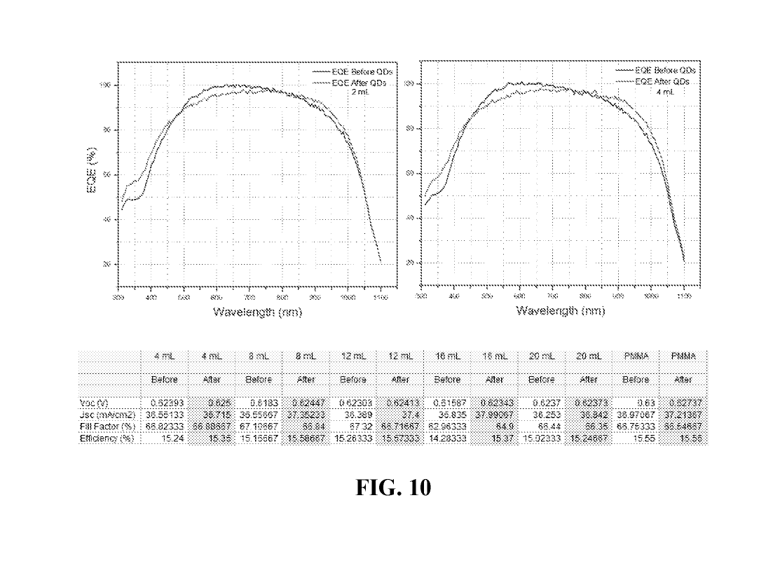

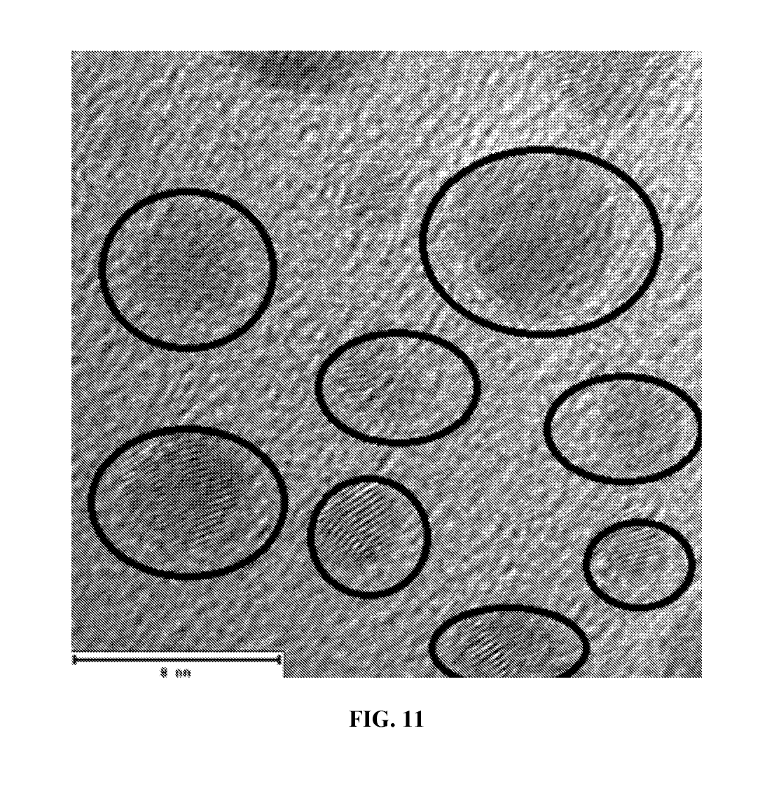

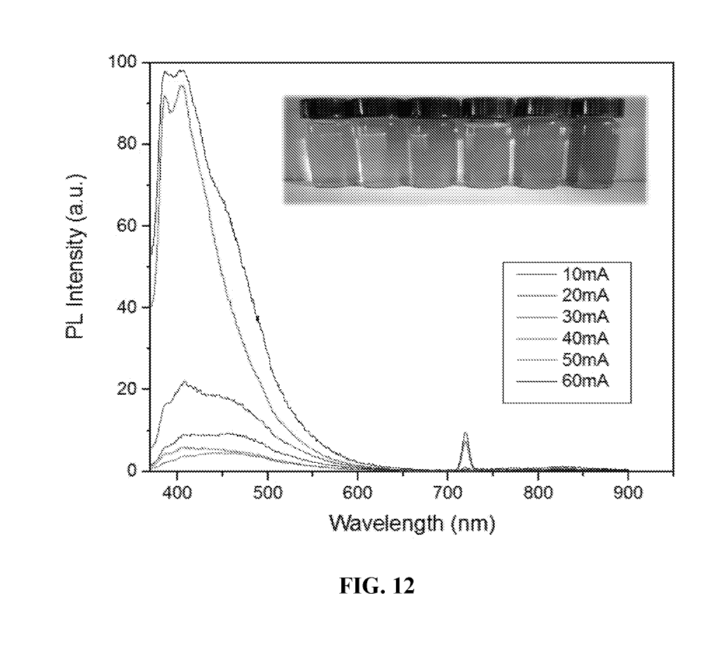

To examine the spectral response of the solar cells without and with the incorporation of the CdTe QDs/PMMA down shifting nanostructures, we measured the EQE of the planar and texturized cells which are plotted in FIG. 6, to measure the number of carriers collected for each solar cell to the number of photons that are absorbed for each solar cells from the given energy on each wavelength. The c-Si solar cells with the down shifting nanostructures have an improvement on the EQE mainly on short wavelengths between 300 and 400 nm, furthermore, the maximum EQE improvement is between 400 to 600 nm due the effect of the CdTe QDs applied to the down shifting nanostructure such absorption and emission has the effect in that wavelength range (FIG. 7), where also on the range of 600 to 900 nm is clearly shown and improvement compared to the reference samples without the CdTe QDs down shifting nanostructures.

The results of the ultimate efficiency of the c-Si structures with the incorporation of the CdTe QDs with emission near 600 nm into the PMMA matrix to form down shifting nanostructures indicated that the optimum thickness to focus to increase the efficiency of the c-Si solar cells is 100 nm following with the optimum concentration 2:1. Following such parameters with the incorporation of the optimum CdTe QDs/PMMA down shifting nanostructure on the incident surface of the fabricated planar and texturized c-Si solar cells of different thickess, shown an improvement in the results of J-V measurements, where the open circuit voltage (V_{oc}) and short circuit current density (J_{sc}) increase which indicate the effect of the CdTe QDs down shifting layer absorbing shorter wavelengths increasing the PCE of each sample approximately 1-1.5% respectively with the bare sample. External quantum efficiency measurements corroborate the enhancement of such parameters contributed by the enhanced optical absorption applying the optimized CdTe QDs/PMMA down shifting nanostructures. The results of the study suggests that the c-Si solar cells with the incorporation of the down shifting nanostructures especially with thinner solar cells are promising candidates for harvesting solar energy to improve the efficiency of such devices.

Synthesis of CdTe QDs and Incorporation of CdTe QDs in PMMA.

CdTe QDs of average size of 2 to 10 nm were synthesized in colloidal solution (Wu et al. J. Mater. Chem., 2012, 22:14573-78). To this end 0.2 mmol of cadmium acetate dihydrate (Cd(CH₃COO)₂.2H₂O, 99.5%) was dissolved into 50 ml deionized water in an Erlenmeyer flask. Then 18 μl of Thioglycolic acid (TGA, 90%) were added and the pH was adjusted with 1 M NaOH solution measured with a H13221 pH Benchtop Meter. After stirring for 5 min, 0.04 mmol of potassium tellurite hydrate (K₂TeO₃, 95%) which was dissolved in 50 ml deionized water in an Erlenmeyer flask and stirred for 5 min was added into the above solution. Then 80 mg of sodium borohydride (NaBH₄, 99.99%) were added into the precursor solution. After the reactions proceeded while stirring for another 5 minutes the solution was transferred to a single neck round bottom flask which was attached to a Liebig condenser, stirred and refluxed at 100° C. in a hot plate under open-air conditions. By controlling the reaction time (30 min, 1 h, 3 h, 6 h, 8 h and 12 h) CdTe QDs with desired PL emission spectra were obtained. All the chemicals were purchased from Sigma Aldrich and employed directly without further purification.

A measured concentration of synthesized CdTe QDs was added into a 2 ml microcentrifuge tube with acetone (1:1), then centrifuged for 5 min at 10,000 rpm, upon the removal of the supernatant, the precipitate was redissolved using a polymer host-matrix of 495 PMMA 2% Anisole to embed it for different ratios of CdTe QDs to PMMA, namely, 2:1, 2:3, 2:7 and 2:10. The mixture was sonicated for 5 min to obtain a homogeneous mixture of PMMA/CdTe QDs.

Luminescent down shifting nanostructures process. The freshly synthesized solution was used for spin casting films with the dispersed CdTe QDs (refluxed: 30 min, 1 h, 6 h, 8 h, 12 h). Films with various thicknesses were prepared by employing a Programmable spin coater, SCU-2008C, Apex Instruments Co. over 20×20 mm square c-Si substrates (n-type, <100>, with a thickness of 620 μm and resistivity 3-20 Ω cm) and cover glasses of 22×22 mm (thickness 0.13-0.17 mm). Prior to spin casting the silicon substrates were cleaned by immersing them in a Piranha solution comprising Sulfuric acid (H₂SO₄) and Hydrogen peroxide (H₂O₂, 30%) in the volume ratio of 3:1 at 80° C. for 10 min. Subsequently, the samples were rinsed with distilled/deionized (DI) water and dried with a N₂ gun. The samples were then subjected to a standard RCA clean process immersing them in a solution consisting of H₂O₂, Ammonium hydroxide (NH₄OH, 37%), and DI water in the volume ratio of 1:1:5 at 80° C. for 10 min then rinsed with DI water and dried with a N₂ gun. In the next step, the samples were immersed in a solution comprised of H₂O₂, Hydrochloric acid (HCl, 37%), and DI water in the volume ratio of 1:1:5 at 80° C. for 10 min. Once more, the samples were then rinsed with DI water and dried with a N₂ gun. The cover glasses were cleaned by sonicating them for 10 min each time, first in water with detergent, then in acetone and isopropyl alcohol (Semaltianos, Microelectronics journal, 2007, 38:754-61) and finally were rinsed with DI water and dried with a N₂ gun. Spin coating was performed by depositing the solution dropwise onto the steady substrate ensuring that the solution covers it completely and then start spinning at 500 rpm for 5 sec and ramping quickly to the final speed (1000, 2000, 3000 and 4000 rpm) at a high acceleration rate and holding the ultimate speed for during 45 sec. After spin coating the substrates were post-baked at 170° C. for 5 min on a hot plate to allow the solvents in the films to evaporate.

Solar Cell Fabrication.

3 cm×3 cm c-Si samples (n-type, <100>, with thicknesses of 620, 300 and 150 μm, and resistivity of 3-20Ω) were cleaned using a Piranha solution for 10 min at 80° C. to remove organic residues, subsequently an RCA clean was carried out to remove other contaminants. Finally, the samples were cleaned using a diluted hydrofluoric acid (HF 2%) solution for 60 s to remove the native oxide, rinsed with water and dried with a N₂ gun.

The random texturization of the samples comprising vertically aligned silicon nanopillars was achieved by employing room temperature, metal assisted chemical etching (MacEtch) methods (Chartier et al., Electrochimica Acta, 2008, 53, 5509-5516; X. Li et al., Current Opinion in Solid State and Materials Science, 2012, 16, 71-81). To this end silver (Ag) nanoparticles were uniformly dispersed on the c-Si substrates by immersing the samples in a solution comprising silver nitrate (AgNO₃, 0.01M), HF (9.75 ml) and DI water (50 ml) for 60 s. Then the c-Si substrates coated with the Ag nanoparticles were immersed in an etching solution comprising H₂O₂, HF and DI water in the volume ratio of 1:3:9. After surface texturization, the Ag nanoparticles were removed by immersing the substrates in an aqueous solution of Nitric acid (HNO₃) for 10 min (P. R. Pudasaini et al., Microelectronic Engineering, 2014, 119, 6-10). Subsequently, for the formation of the p-n junction on the front surface as well as an ohmic contact on the back surface respectively, boron and phosphorous spin on dopant (SOD) solutions were prepared by the sol gel method. This involved the mixing of boron oxide (B₂O₃) or phosphorous pentoxide (P₂O₅), with tetraethoxysilane (TEOS), ethanol (C₂H₅OH) and DI water (P. R. Pudasaini et al., Journal of Physics D: Applied Physics, 2013, 46, 235104). 1 ml of the n-type P₂O₅ solution was spin cast on a live c-Si sample at 300 rpm (10 s) ramping quickly to the final speed of 1000 rpm (1 min) and ending at 300 s (10 s). The p-type B₂O₃ solution was dispensed on the surface of a sacrificial 3 cm×3 cm c-Si sample and spin cast at 300 rpm (10 s) ramping to a final speed of 1000 rpm (1 min) and ending at 300 s (10 s). Subsequently, the sacrificial and the live sample were baked at 120° C. for 15 min to remove the organic solvents. The live c-Si was placed in a furnace with the pristine side facing the surface of the sacrificial sample with the p-type film, both samples were separated 620 μm by employing random pieces of clean silicon wafers for this purpose. The samples were then annealed at 1000° C. for 10 minutes to dope both sides of the live sample, namely, n⁻ one side to ensure an ohmic contact and p⁺ the other side to produce the p-n junction. Upon the annealing step the live sample was immersed in an HF (2%)+H₂O (10:50) solution for 2 min to remove the excess crystals formed during the doping process, this was followed by rinsing with DI water and drying with a N₂ gun.

The metallization was carried out using a VEECO thermal evaporator, tool that was employed to deposit 200 nm aluminum layers on each side of the live samples. The back sides were protected with kapton tape in order to use the deposited Al layer as a back surface reflector while the top surface was patterned with a comb-like mask. Subsequently, upon the removal of the aforementioned tape, the samples were annealed in a furnace at 580° C. for 10 min to obtain ohmic contacts on both sides. Finally, the incorporation of the downshifting PL nanostructures of CdTe QDs/PMMA over the incident surface of the solar cells was performed in the fashion previously described.

The luminescent down shifting effects of the synthesized CdTe QDs were measured using an AMINCO Bowman Series 2 luminescence spectrometer at room temperature. UV/Vis absorption spectra were recorded on a Cary 5000 spectrophotometer. Dynamic light scattering (DLS) with a Zetasizer nano ZS was employed to determine the volumetric QD size distribution. Transmission electron microscopy (TEM) images were obtained using a JEOL 2010-F microscope operating at 200 kV. The thickness and refractive index measurements of the deposited films were carried out using a Rudolph AutoEL III ellipsometer. The optical reflectance spectra measurements were performed by employing the UV-VIS-NIR previously mentioned equipped with integrating spheres. The photovoltaic measurements were performed using a solar simulator Oriel Sol2A under AM1.5G illumination (1000 W/m²) at standard testing conditions. Prior to live sample measurements, the simulator intensity was calibrated with a reference cell from Newport (Irvine Calif., USA) to ensure that the irradiation variation was within 3%. The external quantum efficiency (EQE) measurements of the solar cells were performed using an Oriel QE-PV-SI system.

Synthesis of Silicon Quantum Dots.

The synthesis of silicon quantum dots using a green approach of a single step is presented. An aqueous solution of 1 mL (3-Aminopropyl) trimethoxy-silane (APTES) and 4 mL of deionized water is mixed for 10 minutes by means of magnetic stirring. Then 1.25 mL of 0.1 M sodium ascorbate (AS) is added to the mixture and further agitation is performed for 20 minutes. This procedure takes place in 30 minutes at room temperature and atmospheric pressure. The resulting quantum dots have an intense green florescence under UV irradiation and their size can be controlled by adjusting the ratio of APTES, AS and the reaction time.

Synthesis of C QDs.

The C nanostructures were synthesized employing an alkali-assisted electrochemical fabrication method utilizing graphite rods for both the anode and the cathode, while varying the applied current between 10 and 60 mA. The graphite rods employed had a diameter of 5 mm, a separation of anode to cathode of 25.4 mm, and were submerged 30 mm in an 100 ml electrolyte solution composed of ethanol and water with a volume ratio of 99.5/.05 to which 0.3 g of NaOH were added. The current was applied for one hour immediately upon the submersion of the graphite rods within the specified current range. Subsequently, the samples were stored for 48 hours at room temperature to stabilize them, and the produced solutions were evaporated until obtaining 5 ml for every 100 ml of quantum dot solution. Upon the completion of the evaporation step the samples were separated employing a silica-gel chromatography column with an 100 ml mixture of petroleum ether and diethyl ether with a volume ratio of 30/70. The final step was to evaporate all the solvents in each vial to increase the C quantum dot concentration.

ZnO QDs Synthesis Process.

Zinc Oxide Quantum Dots (ZnO QDs) were synthesized employing a chemical method. In a typical synthesis, 0.02M zinc acetate solution was made by dissolving 0.256 gr of zinc acetate in 70 mL of pure ethanol, and 0.01M lithium hydroxide solution was prepared separately by dissolving 0.125 gr of LiOH in 30 mL of pure ethanol. The reaction was carried out at room temperature by dropwise addition of LiOH solution to zinc acetate solution in constant stirring. The final pH of the solution was achieved to values of 8, 10 and 12. Once the expected pH vale was reached, the solution was placed in ultrasonic bath. After 3 hours of reaction, the solution was completely transparent and presented photoluminescence effect when UV light was applied to the solution. In order to remove the surfactants, also the unreacted products and collect the synthesized nanoparticles, hexane was added to the ZnO QDs solution in a volume ratio of 2:1. The supernatant was removed by decantation after 24 hours. The precipitated ZnO QDs was washed three times and redispersed in ethanol for storage.

1. A solar cell comprising UV protective material comprising photoluminescent UV down shifting particles dispersed in the material or coating a surface of the material positioned between a photoelectric cell and a source of UV light.

2. The solar cell of claim 1, wherein the protective material is a film.

3. The solar cell of claim 1, wherein the protective material is a UV transparent polymer.

4. The solar cell of claim 3, wherein the polymer is PMMA.

5. The solar cell of claim 3, wherein the UV transparent polymer is coated with a material comprising the photoluminescent UV down shifting particles.

6. The solar cell of claim 1, wherein the protective material has a photoluminescent UV down shifting particle density of about 1×10⁴ to 1×10⁷ particle per mm.

7. The solar cell of claim 1, wherein the protective material has a thickness of 50 nm to 10 mm.

8. The solar cell of claim 1, wherein the photoluminescent UV down shifting particles are CdTe, CdSe, CdS, PbS, ZnO, carbon and silicon quantum dots.

9. A UV protective material comprising photoluminescent UV down shifting particles dispersed in the material or coating a surface of the material.

10. The material of claim 9, wherein the photoluminescent particles are quantum dots.

11. The material of claim 10, wherein the quantum dots are metal quantum dots.

12. The material of claim 10, wherein the quantum dots are CdTe, CdSe, CdS, PbS, or ZnO quantum dots.

13. The material of claim 10, wherein the quantum dots are CdTe quantum dots.

14. The material of claim 9, wherein the material is a flexible polymer, rigid polymer, or glass.

15. The material of claim 14, wherein the material is a film or UV transparent polymer.

16. The material of claim 15, wherein the film is propylene.

17. The material of claim 15, wherein the polymer is PMMA.

18. The material of claim 15, wherein the material is incorporated into a solar cell or greenhouse panel.

19. The material of claim 9, wherein the particles are present at a density of about 1×10⁴ to 1×10⁷ particle per mm.

20. The material of claim 9, wherein the material has a thickness of 50 nm to 10 mm.
